(19) United States
(12) Patent Application Publication
(10) Pub. No.: US 2024/0387607 A1
(43) Pub. Date: Nov. 21, 2024

(54) RADIATION RESISTANT SEMICONDUCTOR DEVICE AND METHOD FOR MANUFACTURING SAME

(71) Applicant: Mitsubishi Electric Corporation, Tokyo (JP)

(72) Inventor: Hajime SASAKI, Tokyo (JP)

(73) Assignee: Mitsubishi Electric Corporation, Tokyo (JP)

(21) Appl. No.: 18/691,795

(22) PCT Filed: Oct. 15, 2021
(86) PCT No.: PCT/JP2021/038268

§ 371 Date: Mar. 13, 2024

(51) Int. Cl. H01G 4/30; H01L 21/02; H01L 27/06; H01L 29/51

(52) U.S. Cl. CPC H01L 28/40; H01L 21/0228; H01L 27/0629; H01L 29/517

(57) ABSTRACT

A field effect transistor (4) is formed on a semiconductor substrate (3). A MIM capacitor (5) has a lower electrode (10), an insulation film (11), and an upper electrode (12) which are in order laminated on the semiconductor substrate (3). A metallic element (13) is added to the insulation film (11).

### FIELD

The present disclosure relates to a radiation resistant semiconductor device that is less likely to be destroyed even when irradiation with heavy ions occurs and a method for manufacturing same.

### BACKGROUND

In recent years, demand for artificial satellites for uses in high-speed data communication, GPS, satellite broadcasting, or earth observation has been increasing. Along with this situation, the number of semiconductor devices mounted on a satellite has drastically been increased. However, a semiconductor device to be mounted on a satellite is required to have radiation resistance for operations in a cosmic environment in addition to reliability of a semiconductor device for general ground uses. In the cosmic environment, a semiconductor device will be exposed to heavy ions, protons, and electrons, which would be accelerated to have high energy, or to gamma rays produced when those particles collide with a satellite housing.

In a case where a device is exposed to heavy ions, a large characteristic fluctuation occurs due to a single event effect, and when the fluctuation is very large, the device might be destroyed. This is because heavy ions passing through an inside of the device give energy to a semiconductor and produce a large number of electron-hole pairs around passing loci. A charge distribution and a potential state in the device are modulated by the electron-hole pairs, and a transitional characteristic fluctuation is induced. Note that in a case where the device is exposed to protons or electrons, microscopic crystal defects are produced due to a displacement damage effect, and characteristic degradation is caused. Further, in a case where the device is exposed to gamma rays, charges are accumulated in an internal portion of the device due to a total ionizing dose effect, and a characteristic fluctuation is caused. A semiconductor device to be mounted on a satellite is required to have radiation resistance for enabling the semiconductor device to normally operate even when exposed to those radiations.

It has been disclosed to improve a dielectric breakdown voltage and a leakage current characteristic by doping a dielectric layer of a thin-film capacitor with a metallic element (for example, see PTL 1). However, a doping concentration is limited up to 1010 atoms/cm³. This doping concentration hardly provides an LET decreasing effect for improving radiation resistance.

As a semiconductor device to be mounted on a satellite, demand has lately been rising for a compound semiconductor device with high efficiency, high output, and high efficiency. In addition, in consideration of demands for high frequency and size reduction, a monolithic microwave integrated circuit (MMIC) has been used in which an active element such as a transistor and passive elements such as a capacitor, an inductor, a resistor, and a transmission line are integrated together.

### CITATION LIST

### Patent Literature

[PTL 1] JP 2010-258414 A

### SUMMARY OF THE INVENTION

### Problems to be Solved by the Invention

So far radiation resistance of an active element such as a FET has intensively been studied. However, in a case where an MMIC is mounted on a satellite, not only the FET but also a MIM (metal insulator metal) is irradiated with radiations. In particular, an operating voltage of a GaN-based device attracting attention among compound semiconductors is five to ten times higher compared to an operating voltage of a GaAs-based device. Taking into consideration sneaking from a load line which is characteristic of a high-frequency operation, a voltage approximately three times the operating voltage is applied to the MIM although it is instantaneous. When the timing of application of the high voltage agrees with a passing timing of a heavy ion, the MIM might be destroyed. This is because electron-hole pairs are produced around a locus through which the heavy ion passes in an insulation film of the MIM, work as a current path, and thereby lower insulation.

An object of the present disclosure, which has been made for solving the above-described problems, is to obtain a radiation resistant semiconductor device that is less likely to be destroyed even when irradiated with heavy ions and a method for manufacturing same.

### Solution to Problem

A radiation resistant semiconductor device according to the present disclosure includes: a semiconductor substrate: a field effect transistor formed on the semiconductor substrate; and a MIM capacitor having a lower electrode, an insulation film, and an upper electrode which are in order laminated on the semiconductor substrate, wherein a metallic element is added to the insulation film.

### Advantageous Effects of Invention

In the present disclosure, a metallic element is added to the insulation film of the MIM capacitor. Consequently, the linear energy transfer in heavy ion irradiation is lowered, and a production amount of electron-hole pairs is decreased. Thus, it is possible to obtain a radiation resistant semiconductor device that is less likely to be destroyed even when irradiation with heavy ions occurs and a method for manufacturing same.

### BRIEF DESCRIPTION OF THE DRAWINGS

FIG. 1 is a cross-sectional view illustrating a radiation resistant semiconductor device according to a first embodiment.

FIG. 2 is a cross-sectional view illustrating a semiconductor device according to the comparative example.

FIG. 3 is a diagram illustrating relationships of the LET with energy of heavy ions.

FIG. 4 is a diagram illustrating a relationship between a content rate of Ta and the LET.

FIG. 5 is a diagram illustrating relationships of the LET with energy of heavy ions.

FIG. 6 is a diagram illustrating an energy band structure of the insulation film of the MIM capacitor according to a third embodiment.

FIG. 7 is a cross-sectional view illustrating a method for manufacturing a radiation resistant semiconductor device according to a fifth embodiment.

FIG. 8 is a cross-sectional view illustrating a radiation resistant semiconductor device according to a sixth embodiment.

### DESCRIPTION OF EMBODIMENTS

A radiation resistant semiconductor device and a method for manufacturing same according to the embodiments of the present disclosure will be described with reference to the drawings. The same components will be denoted by the same symbols, and the repeated description thereof may be omitted.

### First Embodiment

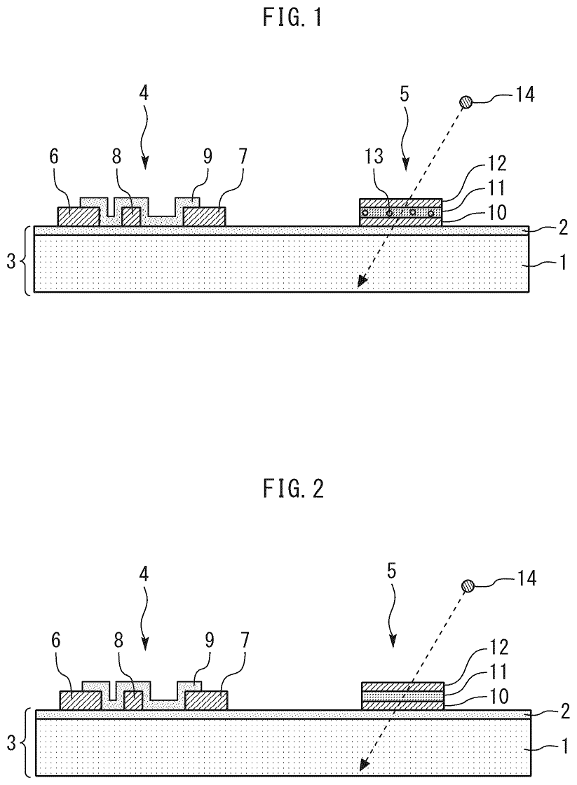

FIG. 1 is a cross-sectional view illustrating a radiation resistant semiconductor device according to a first embodiment. The semiconductor device is an MMIC in which active elements and passive elements are formed on a semiconductor substrate and is a high-frequency semiconductor device which uses a GaN-based semiconductor.

Because a SiC substrate 1 has high thermal conductivity, is semi-insulating, and has a lattice constant close to that of GaN, the SiC substrate 1 is often used for a GaN-based device. A GaN layer 2 serving as an active region is formed on the SiC substrate 1. A semiconductor substrate 3 is formed with the SiC substrate 1 and the GaN layer 2. In FIG. 1, the GaN layer 2 is illustrated as a single layer but is actually formed with plural layers. Specifically, on an interface between the SiC substrate 1 and the GaN layer 2, thin AlN formed at a low temperature is formed as a nucleation layer in order to buffer different lattice constants. On the thin AlN, the GaN layer 2 and an AlGaN layer are in order formed. Two dimensional electron gas (2DEG) due to a piezoelectric charge and spontaneous polarization are produced in the interface between the AlGaN layer and the GaN layer and are used as carriers for a FET operation. Consequently, a layer structure of the semiconductor is formed with, in order from a top, AlGaN, GaN, AlN, and SiC.

A field effect transistor 4 and a MIM capacitor 5 are formed on the GaN layer 2. A source electrode 6, a drain electrode 7, and a gate electrode 8 of the field effect transistor 4 are covered with a protective film 9. The protective film 9 is made of an insulation film of Si₃N₄ or the like formed by plasma CVD. The protective film 9 is illustrated as a single layer in FIG. 1, but because a FET manufacturing step is complicated and insulation films are formed in respective main steps, the protective film 9 has a multi-layer structure.

The MIM capacitor 5 is, as a matching circuit, connected between the gate and a ground or between the drain and the ground of the field effect transistor 4. Further, for example, assuming an MMIC with a multi-stage amplifier, the MIM capacitor 5 is, as a DC-cut circuit, connected between the drain of the field effect transistor 4 in a front stage and the gate of the field effect transistor 4 in a rear stage.

The MIM capacitor 5 has a lower electrode 10, an insulation film 11, and an upper electrode 12, which are in order laminated on the semiconductor substrate 3. The source electrode 6, the drain electrode 7, the gate electrode 8, the lower electrode 10, and the upper electrode 12 are made mainly of gold. Film thicknesses of those electrodes are several ten nanometers to several micrometers. In order to improve adhesiveness or electric contacting characteristics, a thin film of Ti, Ni, Pt, or the like may be formed on a front surface or a back surface of gold. As a material of the gate electrode 8, Pt may be used.

The insulation film 11 is a silicon nitride film or a silicon oxide film, which is formed by plasma CVD or ALD and which is close to Si₃N₄ or SiO of a stoichiometric composition. In order to improve an electrostatic capacity of the MIM capacitor 5, as the insulation film 11, Ta₂O₅, HfO₂, or the like as a high-dielectric material may be used. As the insulation film of the MIM capacitor, a laminated multi-layer film with SiO₂ and Ta₂O₅, each layer of which is approximately 5 to 50 nm, may be used, but the insulation film 11 of the present disclosure is a mixed film. A lower limit of a film thickness of the insulation film 11 is set so as not to exceed a dielectric breakdown field, and an upper limit is set so as to suppress a restriction of a film formation time in a step and to suppress a stress increase. Thus, the film thickness of the insulation film 11 is 20 to 700 nm. In the present embodiment, Ta (tantalum) as a metallic element 13 is added to the insulation film 11.

Next, effects of the present embodiment will be described by a comparison with a comparative example. FIG. 2 is a cross-sectional view illustrating a semiconductor device according to the comparative example. In the comparative example, a metallic element such as Ta is not added to the insulation film 11 of the MIM capacitor 5.

In a case where the field effect transistor 4 performs an amplifier operation, an operating voltage of 50 V, for example, is applied to the drain electrode 7. In this case, the load line is modulated by a capacitor or an inductor under a high-frequency operation, and a higher voltage than the operating voltage might be applied at a moment when sneaking from the load line occurs. Depending on a load state and an input intensity of an amplifier, an approximately three times voltage might be applied although the application occurs momentarily. A high voltage might be applied between the upper electrode 12 and the lower electrode 10 of the MIM capacitor 5 which is, as the matching circuit or the DC-cut circuit, connected with the field effect transistor 4 although the application occurs momentarily.

Atoms of various elements, which are produced by a supernova explosion at the center of the galaxy, are accelerated to have ultra-high energy and penetrate a housing of a satellite, and the device is irradiated with the atoms. In a case where the MIM capacitor 5 is irradiated with a heavy ion 14, the heavy ion 14 gives energy to the insulation film 11 and produces electron-hole pairs around its locus. In this case, when a voltage is applied to the MIM capacitor 5, a production spot of electron-hole pairs becomes an origin of a leakage current, and dielectric breakdown is caused. This is a phenomenon which occurs due to a passage of a single atom and is thus referred to as single event effect.

The energy given to the insulation film 11 by the heavy ion 14 will be referred to as linear energy transfer (LET). When the LET is as low as possible, an influence of the irradiation becomes smaller, and radiation resistance becomes higher. The LET tends to become larger as the atomic number of an irradiation atom becomes larger. In an experiment which simulates a phenomenon in an actual cosmic environment, a xenon (Xe) atom with a large atomic number is often used because of easiness of acceleration by an accelerator. In order to obtain LET dependence, irradiation with Kr or Ar which is lighter may be performed.

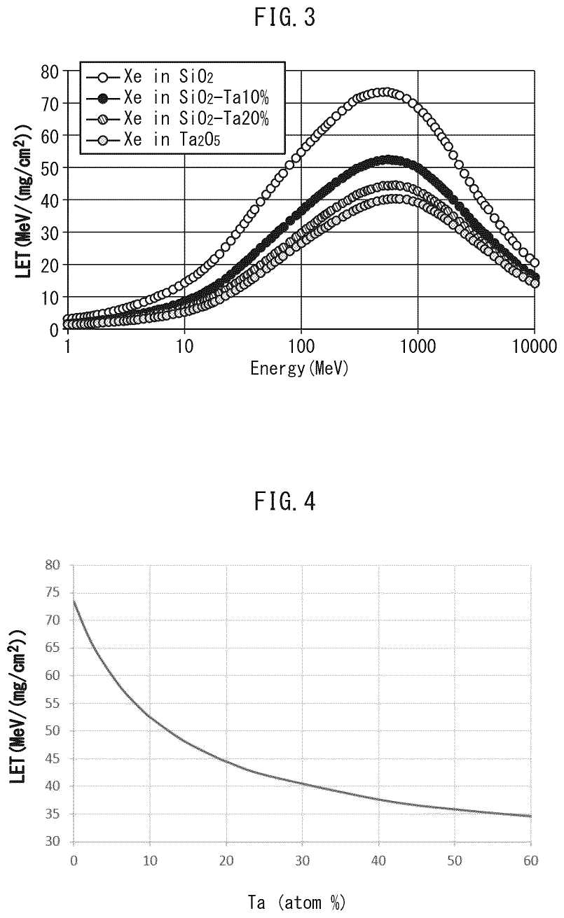

FIG. 3 is a diagram illustrating relationships of the LET with energy of heavy ions. A unit of the LET is MeV/(mg/cm²). In FIG. 3, “Xe in SiO₂” indicates a case of a comparative example where SiO₂ to which no Ta is added is irradiated with Xe. In this case, a maximum value of the LET is indicated around 500 MeV, and the value is about 73 MeV/(mg/cm²). In a case where Si₃N₄ is irradiated with Xe, almost the same LET is obtained. Electron-hole pairs corresponding to this energy transfer amount are produced in the insulation film, and the single event effect is caused. As described above, the LET is high in the comparative example, and destruction is likely to occur.

In FIG. 3, “Xe in SiO₂—Ta10%” indicates a case where SiO₂ to which 10% Ta is added is irradiated with Xe. Compared to 73 MeV/(mg/cm²) of SiO₂, it was possible to decrease the LET at 500 MeV to 52 MeV/(mg/cm²). As described above, it has been found that addition of only 10% Ta leads to an LET decreasing effect of 28%. In FIG. 3, “Xe in SiO₂—Ta20%” indicates a case where SiO₂ to which 20% Ta is added is irradiated with Xe. In this case, the LET at 500 MeV can be lowered to 44 MeV/(mg/cm²).

In FIG. 3, “Xe in Ta₂O₅” indicates a case where Ta₂O₅ is irradiated with Xe. In this case, the LET at 500 MeV is 40 MeV/(mg/cm²). It has newly be found this time that Ta₂O₅ has radiation resistance which is approximately two times higher than those of SiO₂ and Si₃N₄. So far Ta₂O₅ has been attracting attention only as a high dielectric constant film, but a fact that Ta₂O₅ is suitable for a space use is new knowledge.

In the present embodiment, the metallic element 13 is added to the insulation film 11 of the MIM capacitor 5. Consequently, the linear energy transfer in heavy ion irradiation is lowered, and a production amount of electron-hole pairs is decreased. Thus, it is possible to obtain a radiation resistant semiconductor device that is less likely to be destroyed even when irradiation with heavy ions occurs and a method for manufacturing same.

Further, in the present embodiment, an example is described where Ta as the metallic element 13 is added to the insulation film 11, but when the metallic element 13 to be added is an element in one of groups 2 to 6 and one of fourth to sixth periods in the periodic table, the LET decreasing effect can be obtained. For example, oxides to which Hf, W, Zr, Y, La, W or the like is added have made achievements as high dielectric constant films, and mingling those does not give an adverse influence. A result has been obtained that an element of a larger atomic number provides a higher LET lowering effect.

Usually, in a case where doping with or addition of an element is performed, a doping effect is expected by causing the element to form chemical bonding with a parent material. In PTL 1 also, it is considered that elements for doping are caused to form chemical bonding with atoms of a parent material and a leakage current is thereby suppressed. Meanwhile, in the present embodiment, the metallic element 13 is mingled with the insulation film 11, as a stoichiometric oxide and in an inactive state. Consequently, the metallic element 13 does not form chemical bonding with the parent material and does not hinder properties of the parent material.

A concentration of the metallic element 13 added to the insulation film 11 is higher than 1010 atoms/cm³ in PTL 1, but Ta addition of several percent is necessary for obtaining an LET suppressing effect. It is considered that the LET is desirably equivalent to or lower than 60 MeV/(mg/cm²). FIG. 4 is a diagram illustrating a relationship between a content rate of Ta and the LET. It may be understood that the LET becomes 60 or lower at a content rate of 5% or higher. Consequently, the content rate of the metallic element 13 in the insulation film 11 is set to 5% or higher. Meanwhile, the content rate of Ta of 28.6% provides a composition of Ta₂O₅, but because the parent material is changed in quality when the content rate becomes 28.6% or higher, the content rate of the metallic element 13 is set to lower than 28.6%.

Further, in a case where SiO₂ doped with the element Ta is formed by a sputtering technique or a plasma CVD method, it is considered that doping is performed with the element Ta as a single element and is less likely to form a stoichiometric composition such as Ta₂O₅ even when the element Ta is oxidized and that substitutions for Si or oxygen atoms and insertion among SiO molecules also occur. The reason why PTL 1 purposely defines an upper limit of doping is considered to be because when doping is performed to the upper limit or higher, the above unstable structures increase, a leakage current becomes large instead, and an insulation withstand voltage is degraded. Differently from the above, in the present embodiment, the insulation film 11 is formed by using ALD. Accordingly, because film formation of an accurately stoichiometric oxide film is performed, a high quality film can be obtained even when Ta at a high concentration is added.

A relative dielectric constant of SiO₂ is 3.8, and a relative dielectric constant of Ta₂O₅ is 25. A mixture of those has a dielectric constant corresponding to a mixing ratio of respective dielectric constants. In other words, when Ta₂O₅ is added to SiO₂, the dielectric constant becomes high, and an area for obtaining the same electrostatic capacity can be shrunk. A large effect of lowering a collision probability of heavy ions is obtained by shrinking the area although the effect is a subsidiary effect. When addition is performed to a composition close to Ta₂O₅, taking into consideration the dielectric constant, a heavy ion collision probability can be made about six times lower, and its effect is thus enormous. Further, because a chip area can be shrunk, size reduction of the device can be intended, this leads to size reduction of the satellite, and cost reduction can also be realized. Further, the dielectric constant becomes high, and a film thickness for obtaining the same electrostatic capacity can thereby be thickened. Because the film thickness is thick, a field applied to the insulation film is buffered even when an applied voltage is constant, and dielectric breakdown can be suppressed.

Note that in the present embodiment, SiO₂ is used as the parent material of the insulation film 11, but SiN may be used. In the present embodiment, an example of a GaN-based semiconductor device is described, but the semiconductor device may be a GaAs-based, InP-based, or Si-based semiconductor device. In the present embodiment, an example of the MMIC is described, but a discrete capacitor may be used. In the present embodiment, the semiconductor device for uses in space is described, but similar effects are exhibited for a semiconductor device for uses on the ground.

### Second Embodiment

In the present embodiment, in the insulation film 11 of the MIM capacitor 5, 5% Ta and 5% Hf, a total of 10%, are added to SiO₂. Other configurations are similar to those of the first embodiment.

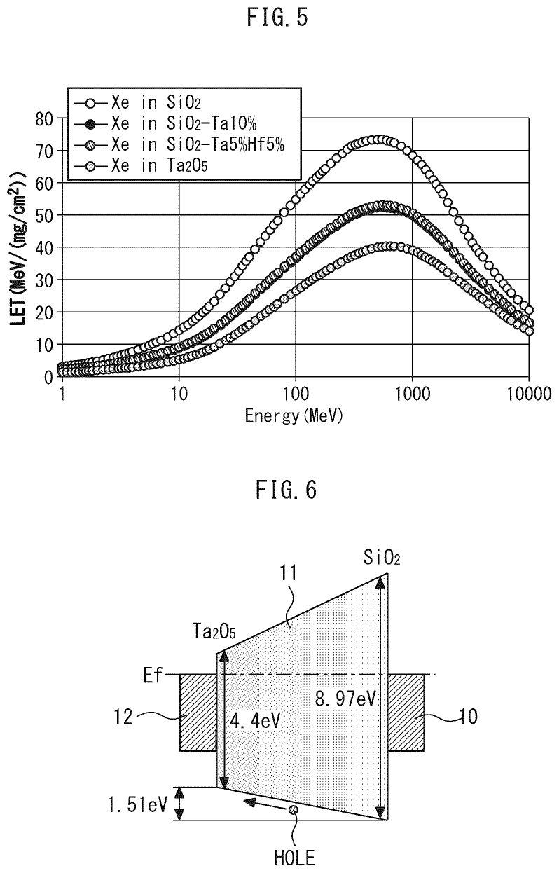

FIG. 5 is a diagram illustrating relationships of the LET with energy of heavy ions. In FIG. 5, “Xe in SiO₂—Ta5% Hf5%” indicates a case where SiO₂ to which 5% Ta and 5% Hf are added is irradiated with Xe. In this case, almost the same effect as a case where 10% Ta is added can be obtained. It has become clear that in a case where plural elements as the metallic elements 13 are added to the insulation film 11, a similar LET lowering effect can be obtained. It is presumed that because the atomic numbers of Ta and Hf neighbor each other, almost the same effect as single addition of Ta is exhibited. Elements from different groups are mixed and added, gaps among atoms and molecules are thereby efficiently filled, and a dense film can be obtained. Note that in a case where plural elements are added as respective stoichiometric oxides, no interaction among the added elements occurs.

### Third Embodiment

In the present embodiment, a composition of the insulation film 11 of the MIM capacitor 5 continuously changes from the lower electrode 10 toward the upper electrode 12. The composition of the insulation film 11 has SiO₂ on the lower electrode 10 side and has Ta₂O₅ on the upper electrode 12 side. Other configurations are similar to those of the first embodiment.

FIG. 6 is a diagram illustrating an energy band structure of the insulation film of the MIM capacitor according to a third embodiment. A one-dot chain line Ef indicates a Fermi level. A bandgap of Ta₂O₅ is 4.4 eV, and a bandgap of SiO₂ is 8.97 eV. Because the composition of the insulation film 11 is gradually changed, taking into consideration a work function, a band structure is provided in which a valence band and a conduction band are inclined as in FIG. 6. In the valence band, a field is produced due to an offset of 1.51 eV even when no voltage is applied. Destruction of the insulation film 11 is accelerated in accordance with an amount and a staying time of electron-hole pairs produced in the heavy ion irradiation. Because mobility of produced holes is slower than that of electrons, the holes stay long in the insulation film 11 and cause destruction. In the present embodiment, the produced holes are quickly moved to an electrode side, and accumulation of charges in the insulation film can thereby be suppressed. Thus, destruction of the MIM capacitor 5 by the heavy ion 14 can be suppressed.

The MIM capacitor 5 is irradiated with the heavy ion 14 from its upper portion with a high probability, and energy of the heavy ion 14 gradually lowers in the insulation film 11. Consequently, a larger effect can be obtained in a case where the composition of the insulation film 11 has Ta₂O₅, in which the LET is low, on the upper electrode 12 side.

In a case where Ta₂O₅ and SiO₂ are laminated, band discontinuity occurs to an interface between Ta₂O₅ and SiO₂ and serves as a barrier, and charges are accumulated. The composition of the insulation film 11 is continuously changed as in the present embodiment, and produced charges can thereby effectively be swept to the electrode.

### Fourth Embodiment

A description will be made about a method for manufacturing a radiation resistant semiconductor device according to a fourth embodiment. As film formation methods for the insulation film, in general, sputtering, vapor deposition, plasma CVD, and so forth are present. An LET reduction effect can be obtained even when the insulation film 11 is formed by those film formation methods, but in the present embodiment, the insulation film 11 is formed by atomic layer deposition (ALD) which can form a denser film. The ALD is a procedure in which organic metal and a precursor of water or ozone are alternately introduced for each layer of atoms and film formation is thereby performed.

When film formation of Ta₂O₅ and SiO₂ is performed for each layer of atoms and an atom ratio is calculated taking into consideration oxygen atoms, Ta occupies 20% of a whole film. In the present embodiment, in order to realize a Ta concentration of 10%, when film formation of Ta₂O₅ is performed, gas introduction is stopped in a state where covering with the precursors is performed for only a half atomic layer. A cycle is repeated in which a half atomic layer of Ta₂O₅ and one atomic layer of SiO₂ are alternately laminated, and the insulation film 11 to which a total of 10% Ta is added can thereby be formed by the ALD. By a similar film formation method, the insulation film 11 of a desired composition can be formed.

A state where one complete layer of atoms is not formed and where island-like lumps of atoms, the lumps having one-atom heights, or individual atoms are scattered is referred to as submonolayer. Because usually a purpose of the ALD is film formation for each layer of atoms, no related art is present in which film formation is performed with the submonolayer in order to accurately control a composition ratio. On the other hand, in the present embodiment, the insulation film 11 is formed by performing, by the ALD, film formation of two or more kinds of films for each submonolayer equivalent to or smaller than one atomic layer.

Film formation is performed for each submonolayer, and the metallic element 13 can thereby almost uniformly be distributed in the insulation film 11. Thus, local production distribution of electron-hole pairs produced due to the heavy ion irradiation can be suppressed, and a highly radiation resistant semiconductor device can be obtained which is less likely to be destroyed. Further, because the ALD is used and a stoichiometric oxide film can thereby be formed even when film formation is performed for each submonolayer, a dense film in which few defects are present and little leakage current occurs can be obtained.

Further, two or more kinds of precursors are simultaneously introduced in film formation of a single layer of atoms by the ALD, and film formation of a composite material film may thereby be performed for each layer of atoms. For example, in film formation of one atomic layer, the film is formed by the ALD by using mixed gas of a precursor for forming SiO₂ and a precursor for forming Ta₂O₅, and the insulation film 11 to which 10% Ta is added can thereby be formed as well. Further, in the present embodiment, a description is made about the film formation method for the oxide film, but the same applies to a case where the parent material of the insulation film 11 is Si₃N₄. In this case, NH₃ or the like is used as a precursor for nitrodization, and a reaction is assisted by plasma in order to promote the reaction.

### Fifth Embodiment

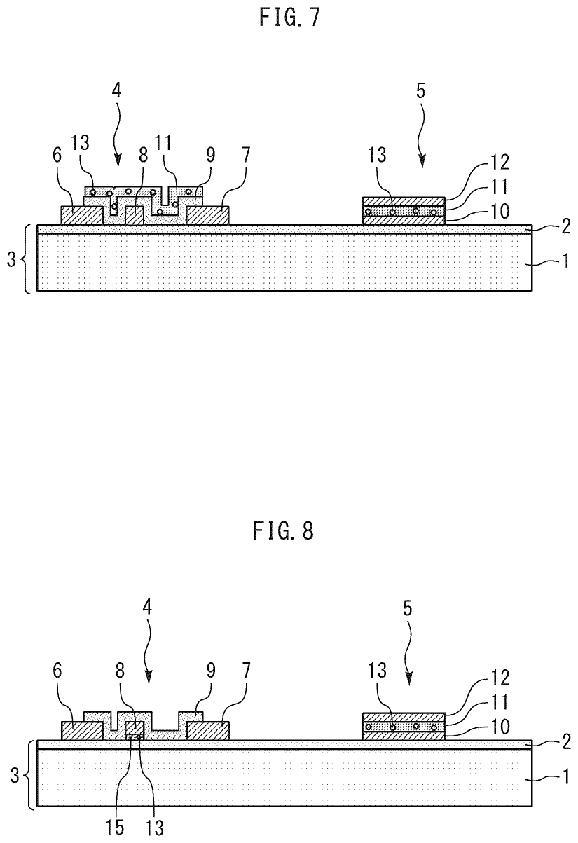

FIG. 7 is a cross-sectional view illustrating a method for manufacturing a radiation resistant semiconductor device according to a fifth embodiment. First, the semiconductor substrate 3 is prepared in which the GaN layer 2 is formed on the SiC substrate 1. The source electrode 6, the drain electrode 7, and the lower electrode 10 are formed on the semiconductor substrate 3. Next, the field effect transistor 4 is formed by forming the gate electrode 8. The protective film 9 to which the metallic element 13 is not added is formed to cover the field effect transistor 4. Next, the insulation films 11 to which the metallic element 13 is added are simultaneously formed on the protective film 9 and the lower electrode 10. Because the active elements and the passive elements are formed on the same substrate in the MMIC in such a manner, film formation for both of those can be performed in the same film formation process. Accordingly, one step can be reduced from the number of steps. Finally, the upper electrode 12 is formed.

The dielectric constant of the insulation film 11 becomes high by addition of the metallic element 13. When a high dielectric constant film is present close to the semiconductor in a FET which performs a high-frequency operation, a parasitic capacitance is produced, and high-frequency characteristics are lowered. Accordingly, in the present embodiment, the insulation film 11 is formed on the protective film 9 after film formation of the protective film 9, and the insulation film 11 is thereby caused not to directly contact with the GaN layer 2. When the protective film 9 has a multi-layer structure, film formation is performed so as to form the protective film 9 as a final film as long as it is possible. Accordingly, a distance from the semiconductor can be made long, and an increase in the parasitic capacitance can thereby be suppressed.

Further, the insulation film 11 is in addition formed for the field effect transistor 4, energy of the heavy ion 14 is thereby caused to wear out, and an influence of the heavy ion on the field effect transistor 4 can be lowered. In addition, because the insulation film 11 is formed by the ALD, the insulation film 11 has high coatability and is dense compared to a CVD film. Consequently, abilities of the device to block influences of humidity, oxygen, and impurity to which the device is exposed in an operating environment are improved.

Usually, a protective film of a transistor has a multi-layer structure. Because the dielectric constant of the insulation film 11 to which the metallic element 13 is added is increased, the parasitic capacitance is increased when the insulation film 11 directly contacts with the semiconductor substrate 3, and high-frequency performance of the field effect transistor 4 might thereby be lowered. Accordingly, in the present embodiment, the insulation film 11 is not formed in a lowest layer which directly contacts with the semiconductor substrate 3 but is performed such that the insulation film 11 becomes a film close to a highest layer, the film being as far as possible from the semiconductor substrate 3. Because the insulation film 11 does not directly contact with the semiconductor substrate 3, a highly radiation resistant semiconductor device can be obtained while the high-frequency characteristics are maintained.

### Sixth Embodiment

FIG. 8 is a cross-sectional view illustrating a radiation resistant semiconductor device according to a sixth embodiment. In the present embodiment, a gate insulation film 15 to which the metallic element 13 is added is formed on the semiconductor substrate 3. The gate electrode 8 of the field effect transistor 4 is formed on the gate insulation film 15. Consequently, the field effect transistor 4 has a MIS structure in which the gate insulation film 15 to which the metallic element 13 is added is inserted between the gate electrode 8 and the GaN layer 2. Other configurations are similar to those of the first embodiment.

So far Al₂O₃, SiO₂, or the like has been used for the gate insulation film of the MIS structure of the GaN-based device. In a case where the insulation film is irradiated with heavy ions, destruction of the FET occurs similarly to the MIM capacitor. This is because as described in the first embodiment, the LET of SiO₂ with respect to Xe at 500 MeV is as large as 73 MeV/(mg/cm²) and even the LET of Al₂O₃ is as large as 73 MeV/(mg/cm²).

Thus, in the present embodiment, the metallic element 13 is added to the gate insulation film 15. Accordingly, destruction due to the heavy ion irradiation can be suppressed by lowering the LET, and the field effect transistor 4 can thereby be obtained which has high radiation resistance. As described in the first embodiment, the metallic element 13 does not have to be Ta, and the LET decreasing effect can be obtained when the metallic element 13 is an element in one of groups 2 to 6 and one of fourth to sixth periods in the periodic table.

Further, steps can be reduced by simultaneously forming the insulation film 11 of the MIM capacitor 5 and the gate insulation film 15 of the field effect transistor 4. Meanwhile, in a case where different Ta addition amounts or film thicknesses are set for both of the insulation film 11 and the gate insulation film 15 for an improvement in characteristics, different steps are used.

Note that in the present embodiment, the GaN-based device is described, but as long as the MIS structure is provided, a SiC device may be used, other compound semiconductor devices may be used, and further a Si-based MIS or MOS structure may be used.

### REFERENCE SIGNS LIST

3 semiconductor substrate; 4 field effect transistor, 5 MIM capacitor, 9 protective film; 10 lower electrode; 11 insulation film; 12 upper electrode; 13 metallic element; 15 gate insulation film

1. A radiation resistant semiconductor device comprising:
a semiconductor substrate;
a field effect transistor formed on the semiconductor substrate; and
a MIM capacitor having a lower electrode, an insulation film, and an upper electrode which are in order laminated on the semiconductor substrate,
wherein a metallic element is added to the insulation film, and
the metallic element is mingled with the insulation film as a stoichiometric oxide and is an element in one of groups 2 to 6 and one of fourth to sixth periods.

2. (canceled)

3. (canceled)

4. The radiation resistant semiconductor device according to claim 1, wherein a content rate of the metallic element in the insulation film is equal to or higher than 5% and lower than 28.6%.

5. The radiation resistant semiconductor device according to claim 1, wherein plural elements are added to the insulation film as the metallic element.

6. A radiation resistant semiconductor device comprising:
a semiconductor substrate;
a field effect transistor formed on the semiconductor substrate; and
a MIM capacitor having a lower electrode, an insulation film, and an upper electrode which are in order laminated on the semiconductor substrate,
wherein a metallic element is added to the insulation film,
the metallic element is an element in one of groups 2 to 6 and one of fourth to sixth period, and
a composition of the insulation film continuously changes from the lower electrode toward the upper electrode.

7. A radiation resistant semiconductor device comprising:
a semiconductor substrate;
a field effect transistor formed on the semiconductor substrate; and
a MIM capacitor having a lower electrode, an insulation film, and an upper electrode which are in order laminated on the semiconductor substrate,
wherein a metallic element is added to the insulation film,
the metallic element is an element in one of groups 2 to 6 and one of fourth to sixth period,
a composition of the insulation film continuously changes from the lower electrode toward the upper electrode, and
the composition of the insulation film has SiO₂ on the lower electrode side and has Ta₂O₅ on the upper electrode side.

8. A method for manufacturing a radiation resistant semiconductor device comprising:
forming a field effect transistor on a semiconductor substrate; and
laminating a lower electrode, an insulation film to which a metallic element is added, and an upper electrode in order on the semiconductor substrate to form a MIM capacitor,
wherein the metallic element is mingled with the insulation film as a stoichiometric oxide and is an element in one of groups 2 to 6 and one of fourth to sixth periods.

9. (canceled)

10. (canceled)

11. The method for manufacturing a radiation resistant semiconductor device according to claim 8, wherein a content rate of the metallic element in the insulation film is equal to or higher than 5% and lower than 28.6%.

12. A method for manufacturing a radiation resistant semiconductor device comprising:
forming a field effect transistor on a semiconductor substrate; and
laminating a lower electrode, an insulation film to which a metallic element is added, and an upper electrode in order on the semiconductor substrate to form a MIM capacitor,
wherein the metallic element is an element in one of groups 2 to 6 and one of fourth to sixth periods, and
the insulation film is formed by performing, by atomic layer deposition, film formation of two or more kinds of films for each submonolayer equivalent to or smaller than one atomic layer.

13. A method for manufacturing a radiation resistant semiconductor device comprising:
forming a field effect transistor on a semiconductor substrate; and
laminating a lower electrode, an insulation film to which a metallic element is added, and an upper electrode in order on the semiconductor substrate to form a MIM capacitor,
wherein the insulation film is formed by atomic layer deposition by using mixed gas of a precursor for forming SiO₂ and a precursor for forming Ta₂O₅.

14. The method for manufacturing a radiation resistant semiconductor device according to claim 8, comprising:
forming a protective film covering the field effect transistor and to which the metallic element is not added; and
forming the insulation film simultaneously on the protective film and the lower electrode.

15. The method for manufacturing a radiation resistant semiconductor device according to claim 14, wherein the insulation film does not directly contact with the semiconductor substrate.

16. The method for manufacturing a radiation resistant semiconductor device according to claim 8, comprising:
forming a gate insulation film to which the metallic element is added on the semiconductor substrate; and
forming a gate electrode of the field effect transistor on the gate insulation film.

17. The method for manufacturing a radiation resistant semiconductor device according to claim 16, wherein the insulation film and the gate insulation film are simultaneously formed.
